(19) United States
(12) Patent Application Publication
(10) Pub. No.: US 2023/0290757 A1
(43) Pub. Date: Sep. 14, 2023

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Tatsuya OHGURO, Kanazawa Ishikawa (JP)

(21) Appl. No.: 17/885,838

(22) Filed: Aug. 11, 2022

(30) Foreign Application Priority Data
Mar. 9, 2022 (JP) 2022-036291

(51) Int. Cl. H01L 25/07; H01L 23/00

(52) U.S. Cl. CPC H01L 25/074; H01L 24/32; H01L 2224/32145; H01L 2924/13091

(57) ABSTRACT

A semiconductor device includes a substrate, a first chip, a second chip, a first connector, and a second connector. The substrate has a second thickness. The first chip includes a first surface facing the substrate, a second surface positioned at a side opposite to the first surface, a first electrode located at the first surface and electrically connected to the substrate, and a second electrode located at the second surface. The second connector includes a first part positioned above the second chip. A difference between the second thickness and a first thickness of the first part is not more than 20% of the greater of the first thickness or the second thickness.

### CROSS-REFERENCE TO RELATED APPLICATIONS

This application is based upon and claims the benefit of priority from Japanese Patent Application No. 2022-036291, filed on Mar. 9, 2022; the entire contents of which are incorporated herein by reference.

### FIELD

Embodiments relate to a semiconductor device.

### BACKGROUND

There are cases where chips of power semiconductors such as MOSFETs (Metal-Oxide-Semiconductor Field-Effect Transistors) or the like are connected in parallel so that a large current can be output while suppressing the on-resistance.

### BRIEF DESCRIPTION OF THE DRAWINGS

FIG. 1 is a top view showing a semiconductor device according to a first embodiment;

FIG. 2 is a top view showing a substrate, a first lead, a second lead, and a first chip of the semiconductor device according to the first embodiment;

FIG. 3 is a top view showing the substrate, the first lead, the second lead, the first chip, a first connector, and a third connector of the semiconductor device according to the first embodiment;

FIG. 4 is a cross-sectional view along line A-A′ of FIG. 1;

FIG. 5 is a cross-sectional view along line B-B′ of FIG. 1;

FIG. 6 is a circuit diagram of the semiconductor device according to the first embodiment;

FIG. 7 is an evaluation circuit of semiconductor devices according to reference examples and examples;

FIG. 8 is a graph showing a relationship between a breakdown voltage and a current ratio Tr1/Tr2;

FIG. 9 is a graph showing an effect of stacking chips, in which the horizontal axis is a chip area of one chip, and the vertical axis is a reduction rate of an on-resistance due to connecting two stacked chips in parallel;

FIG. 10 is a cross-sectional view showing a semiconductor device according to a second embodiment;

FIG. 11 is a cross-sectional view showing a semiconductor device according to a third embodiment;

FIG. 12 is a histogram in which the horizontal axis is a current flowing in the chip when avalanche breakdown occurred, and the vertical axis is an occurrence frequency of chips measured at each current; and

FIG. 13 is a cross-sectional view showing a semiconductor device according to a fourth embodiment.

### DETAILED DESCRIPTION

In general, according to one embodiment, a semiconductor device includes a substrate, a first chip, a second chip, a first connector, and a second connector. The substrate has a second thickness and is electrically-conductive. The first chip includes a first surface facing the substrate, a second surface positioned at a side opposite to the first surface, a first electrode located at the first surface and electrically connected to the substrate, and a second electrode located at the second surface. The second chip includes a third surface facing the second surface, a fourth surface positioned at a side opposite to the third surface, a third electrode located at the third surface, and a fourth electrode located at the fourth surface. The first connector is located between the second electrode and the third electrode. The first connector is electrically connected to the second and third electrodes. The second connector is electrically connected to the substrate and the fourth electrode. The second connector includes a first part positioned above the second chip. A difference between the second thickness and a first thickness of the first part is not more than 20% of the greater of the first thickness or the second thickness.

Exemplary embodiments will now be described with reference to the drawings.

The drawings are schematic or conceptual and are simplified as appropriate. The relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

An XYZ orthogonal coordinate system is used for easier understanding of the following description. Among the Z-directions, the direction of the arrow is taken as an “upward direction”, and the opposite direction is taken as a “downward direction”; however, these directions are relative and are independent of the direction of gravity. Among the directions in which an X-axis extends, the direction of the arrow also is called the “+X direction”, and the opposite direction also is called the “−X direction”. Among the directions in which a Y-axis extends, the direction of the arrow also is called the “+Y direction”, and the opposite direction also is called the “−Y direction”.

### First Embodiment

First, a first embodiment will be described.

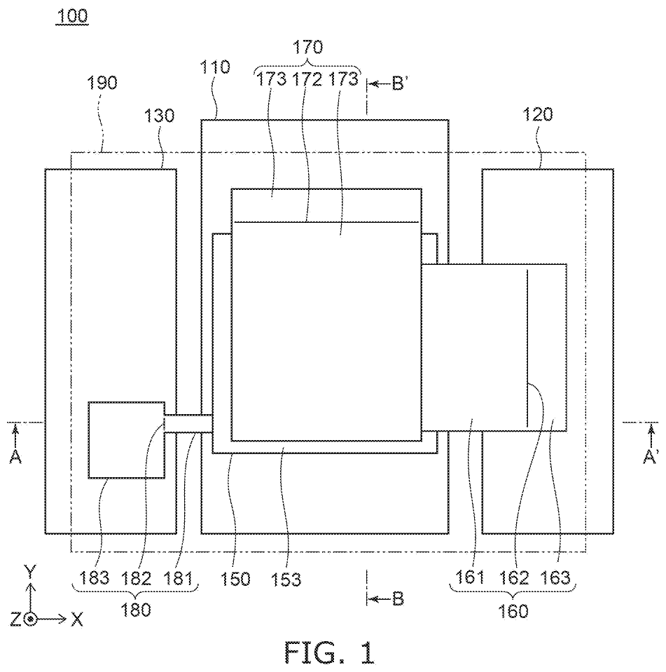

FIG. 1 is a top view showing a semiconductor device according to the embodiment.

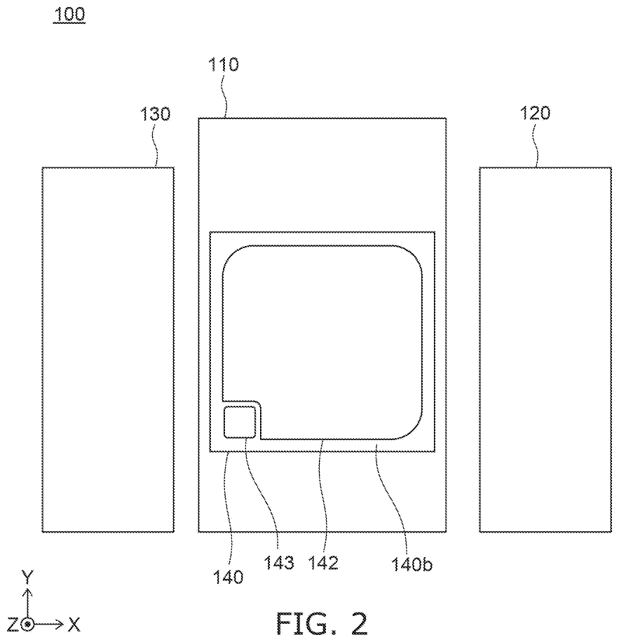

FIG. 2 is a top view showing a substrate, a first lead, a second lead, and a first chip of the semiconductor device according to the embodiment.

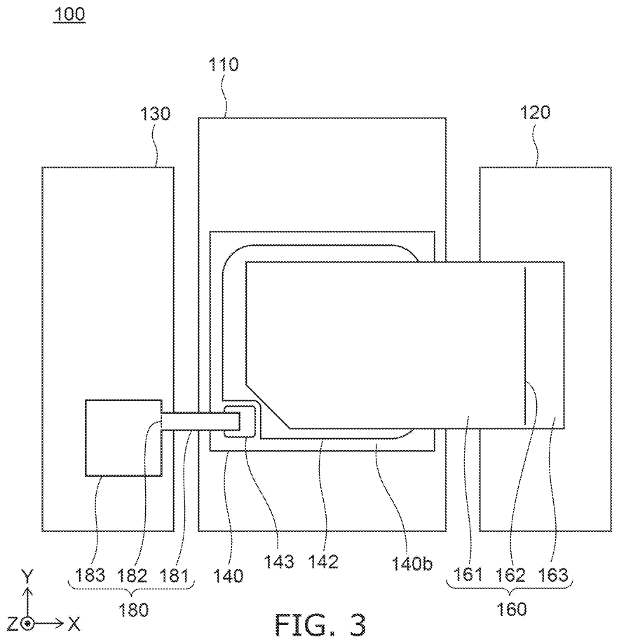

FIG. 3 is a top view showing the substrate, the first lead, the second lead, the first chip, a first connector, and a third connector of the semiconductor device according to the embodiment.

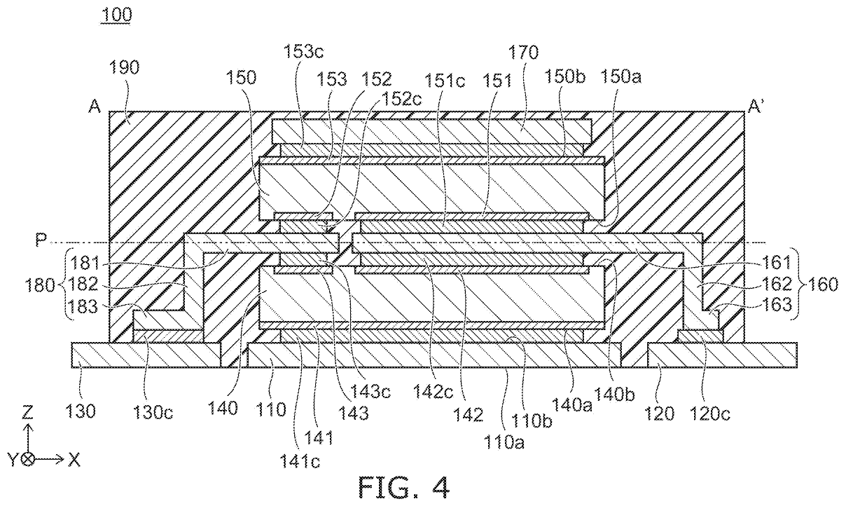

FIG. 4 is a cross-sectional view along line A-A′ of FIG. 1.

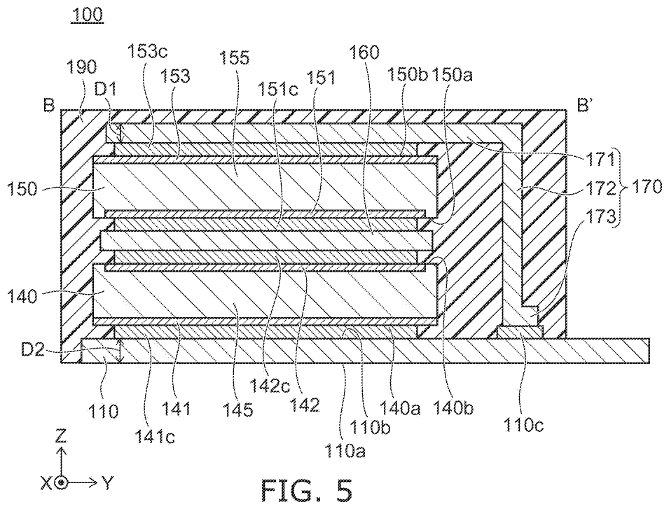

FIG. 5 is a cross-sectional view along line B-B′ of FIG. 1.

As shown in FIGS. 1 and 4, generally speaking, a semiconductor device 100 according to the embodiment includes a substrate 110, a first lead 120, a second lead 130, a first chip 140, a second chip 150, a first connector 160, a second connector 170, a third connector 180, and a resin member 190. The resin member 190 is shown by a double dot-dash line for easier understanding of the internal structure of the semiconductor device 100 in FIG. 1. The components of the semiconductor device 100 will now be elaborated.

For example, the substrate 110 is made of a metal material. For example, metals such as copper and the like that have good heat dissipation are examples of the metal material included in the substrate 110. For example, the substrate 110 has a substantially flat plate shape. Specifically, as shown in FIG. 4, a lower surface 110a and an upper surface 110b of the substrate 110 are substantially flat and are substantially parallel to the X-Y plane. However, the shape of the substrate is not limited to the description above.

For example, the first lead 120 is made of a metal material. Materials similar to the material included in the substrate 110 are examples of the metal material included in the first lead 120. As shown in FIG. 1, the first lead 120 is positioned at the +X side of the substrate 110 and is separated from the substrate 110. For example, the first lead 120 has a substantially flat plate shape. However, the position and the shape of the first lead are not limited to the description above.

For example, the second lead 130 is made of a metal material. Materials similar to the material included in the substrate 110 are examples of the metal material included in the second lead 130. The second lead 130 is positioned at the −X side of the substrate 110 and is separated from the substrate 110 and the first lead 120. For example, the second lead 130 has a substantially flat plate shape. However, the position and the shape of the second lead are not limited to the description above.

As shown in FIG. 2, the first chip 140 is located on the substrate 110. The first chip 140 is, for example, a MOSFET that includes a FP (Field Plate) electrode. However, the first chip may be a MOSFET that does not include a FP electrode, or another type of semiconductor element. For example, the first chip 140 has a substantially flat plate shape. Specifically, the first chip 140 is substantially rectangular when viewed in top-view. As shown in FIG. 4, the surfaces of the first chip 140 include a lower surface 140a facing the substrate 110, and an upper surface 140b positioned at the side opposite to the lower surface 140a.

As shown in FIG. 5, the first chip 140 includes a semiconductor part 145. The semiconductor part 145 is made of a semiconductor material such as silicon, etc.; and impurities are locally introduced to set the conductivity type to an n-type or a p-type. A drain electrode 141 is located at the lower surface 140a of the first chip 140. The drain electrode 141 is electrically connected to the substrate 110 by an electrically-conductive bonding layer 141c such as solder, etc. Here, “the electrode is located at the surface” means that at least a portion of the surface of the electrode is exposed at the surface. According to the embodiment, the bonding layer 141c contacts both the substrate 110 and the drain electrode 141. A source electrode 142 and a gate electrode 143 are located at the upper surface 140b of the first chip 140.

As shown in FIG. 2, the shape of the source electrode 142 when viewed from above, i.e., from the +Z direction, is a quadrilateral with a notch at one corner and with the other corners rounded. The gate electrode 143 is separated from the source electrode 142 and is located in the notched corner region of the source electrode 142. When viewed in top-view, the gate electrode 143 is substantially quadrilateral with rounded corners. The gate electrode 143 is separated from the source electrode 142. However, the positions and shapes of the source electrode and the gate electrode are not limited to the description above.

The second chip 150 is, for example, the same semiconductor element as the first chip 140. Specifically, the second chip 150 is a MOSFET that includes a FP electrode. According to the embodiment, the chip area and shape of the second chip 150 are substantially the same as the chip area and shape of the first chip 140. The “chip area” refers to the surface area in the X-Y plane.

As shown in FIG. 4, the second chip 150 is located above the first chip 140. The surfaces of the second chip 150 include a lower surface 150a facing the upper surface 140b of the first chip 140, and an upper surface 150b positioned at the side opposite to the lower surface 150a.

As shown in FIG. 5, the second chip 150 includes a semiconductor part 155. The semiconductor part 155 is made of a semiconductor material such as silicon, etc.; and impurities are locally introduced to set the conductivity type to the n-type or the p-type. A source electrode 151 and a gate electrode 152 are located at the lower surface 150a of the second chip 150. A drain electrode 153 is located at the upper surface 150b of the second chip 150.

The source electrode 151 of the second chip 150 faces the source electrode 142 of the first chip 140. The shape of the source electrode 151 of the second chip 150 is substantially the same as the shape of the source electrode 142 of the first chip 140. The surface area of the source electrode 151 of the second chip 150 is substantially equal to the surface area of the source electrode 142 of the first chip 140.

The gate electrode 152 of the second chip 150 faces the gate electrode 143 of the first chip 140. The shape of the gate electrode 152 of the second chip 150 is substantially the same as the shape of the gate electrode 143 of the first chip 140. The surface area of the gate electrode 152 of the second chip 150 is substantially equal to the surface area of the gate electrode 143 of the first chip 140.

Accordingly, the first chip 140 and the second chip 150 are substantially symmetrically located with respect to a plane P that is substantially parallel to the X-Y plane and passes through the center of a gap between the first chip 140 and the second chip 150. However, the positions and shapes of the source electrode and the gate electrode are not limited to the description above.

It is favorable for the surface area of the first chip 140 and the surface area of the second chip 150 when viewed from above each to be not less than 10 mm² and not more than 25 mm². However, the surface areas of the chips are not limited to the description above.

The first connector 160 is electrically connected to the source electrode 142 of the first chip 140, the source electrode 151 of the second chip 150, and the first lead 120. For example, the first connector 160 is made of a metal material, etc. A material similar to the material included in the substrate 110 can be used as the metal material included in the first connector 160. For example, the first connector 160 is formed by bending one copper plate.

The first connector 160 includes a first part 161 positioned above the first chip 140, a second part 162 extending from the first part 161 toward the first lead 120, and a third part 163 that is linked to the lower end of the second part 162 and extends along the front surface of the first lead 120.

For example, the first part 161 has a substantially flat plate shape that is substantially parallel to the X-Y plane. The first part 161 is located between the two source electrodes 142 and 151 and extends further in the +X direction than the first and second chips 140 and 150 when viewed from above. The first part 161 is connected to the source electrode 142 of the first chip 140 by an electrically-conductive bonding layer 142c such as solder, etc. Also, the first part 161 is connected to the source electrode 151 of the second chip 150 by an electrically-conductive bonding layer 151c such as solder, etc.

According to the embodiment, the second part 162 is linked to the +X direction end portion of the first part 161 and extends in the downward direction. The third part 163 extends in the +X direction from the lower end of the second part 162. The third part 163 is connected to the first lead 120 by an electrically-conductive bonding layer 120c such as solder, etc. However, the shape of the first connector 160 is not limited to the description above.

The third connector 180 is electrically connected to the gate electrode 143 of the first chip 140, the gate electrode 152 of the second chip 150, and the second lead 130. The third connector 180 can include a material similar to the material included in the first connector 160. For example, the third connector 180 is formed by bending one copper plate.

The third connector 180 includes a first part 181 positioned above the first chip 140, a second part 182 extending from the first part 181 toward the second lead 130, and a third part 183 that is linked to the lower end of the second part 182 and extends along the front surface of the second lead 130.

For example, the first part 181 has a substantially flat plate shape that is substantially parallel to the X-Y plane. The first part 181 is located between the two gate electrodes 143 and 152 and protrudes further in the −X direction than the first and second chips 140 and 150 when viewed from above. The first part 181 is connected to the gate electrode 143 of the first chip 140 by an electrically-conductive bonding layer 143c such as solder, etc. The first part 181 is connected to the gate electrode 152 of the second chip 150 by an electrically-conductive bonding layer 152c such as solder, etc.

According to the embodiment, the second part 182 is linked to the −X direction end portion of the first part 181 and extends in the downward direction. The third part 183 extends in the −X direction from the lower end of the second part 182. The third part 183 is connected to the second lead 130 by an electrically-conductive bonding layer 130c such as solder, etc. However, the shape of the third connector 180 is not limited to the description above.

As shown in FIG. 5, the second connector 170 is electrically connected to the substrate 110 and the drain electrode 153 of the second chip 150. For example, the second connector 170 is made of the same material as the substrate 110. For example, the second connector 170 is formed by bending one copper plate.

The second connector 170 includes a first part 171 positioned above the second chip 150, a second part 172 extending from the first part 171 to the substrate 110, and a third part 173 that is linked to the lower end of the second part 172 and extends along the front surface of the substrate 110.

For example, the first part 171 has a substantially flat plate shape that is substantially parallel to the X-Y plane. The first part 171 covers the drain electrode 153 of the second chip 150 when viewed from above and extends further in the +Y direction than the first and second chips 140 and 150 when viewed from above. The first part 171 is connected to the drain electrode 153 of the second chip 150 by an electrically-conductive bonding layer 153c such as solder, etc.

According to the embodiment, the second part 172 is linked to the +Y direction end portion of the first part 171 and extends in the downward direction. The third part 173 extends in the +Y direction from the lower end of the second part 172. The third part 173 is connected to the substrate 110 by an electrically-conductive bonding layer 110c such as solder, etc. It is favorable for the thickness of the second part 172 to be equal to the thickness of the first part 171 or less than the thickness of the first part 171. By setting the thickness of the second part 172 to be less than the thickness of the first part 171, it is easier to form the second connector 170 by bending. However, the shape of the second connector 170 is not limited to the description above.

According to the embodiment, a first thickness D1 of the first part 171 is less than a second thickness D2 of the portion of the substrate 110 overlapping the drain electrode 141 when viewed from above. It is favorable for the difference between the first thickness D1 and the second thickness D2 to be not more than 20% of the second thickness D2. However, the first thickness may be greater than the second thickness. In such a case, it is favorable for the difference between the second thickness and the first thickness to be not more than 20% of the first thickness. The first thickness may be equal to the second thickness. In other words, it is favorable for the difference between the first thickness and the second thickness to be not more than 20% of the greater of the first thickness or the second thickness. In other words, it is favorable for the thicknesses D1 and D2 to satisfy the following formulas.

(D2−D1)/D2×100≤20(D1≤D2)

(D1−D2)/D1×100≤20(D1≥D2)

The resin member 190 seals the first chip 140, the second chip 150, the first connector 160, the second connector 170, and the third connector 180. As shown in FIG. 1, FIG. 4, and FIG. 5, the resin member 190 does not cover the +Y direction end portion of the substrate 110 and the lower surface 110a of the substrate 110. The portion of the substrate 110 that is not covered with the resin member 190 functions as a connection terminal that connects the two drain electrodes 141 and 153 to the outside. The resin member 190 does not cover the +X direction end portion of the first lead 120 and the lower surface of the first lead 120. The portion of the first lead 120 that is not covered with the resin member 190 functions as a connection terminal that connects the two source electrodes 142 and 151 to the outside. The resin member 190 does not contact the −X direction end portion of the second lead 130 and the lower surface of the second lead 130. The portion of the second lead 130 that is not covered with the resin member 190 functions as a connection terminal that connects the two gate electrodes 143 and 152 to the outside. For example, the resin member 190 is made of a resin material such as a thermosetting resin, etc.

It is favorable for the breakdown voltages of the first and second chips 140 and 150 to be, for example, greater than 0 V and not more than 100 V. However, the breakdown voltages of the first and second chips 140 and 150 are not limited to the description above.

Effects of the embodiment will now be described.

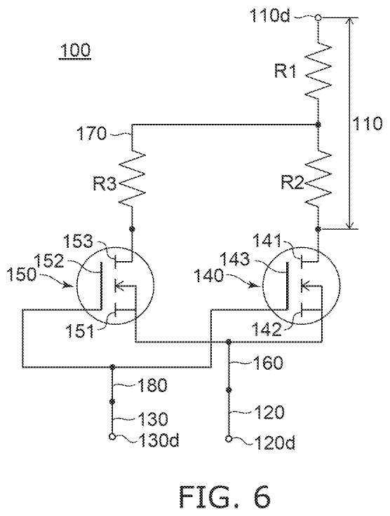

FIG. 6 is a circuit diagram of the semiconductor device according to the embodiment.

In the semiconductor device 100 of FIG. 6, the connection terminal of the two drain electrodes 141 and 153 to the outside is shown by the reference numeral 110d, the connection terminal of the two source electrodes 142 and 151 to the outside is shown by the reference numeral 120d, and the connection terminal of the two gate electrodes 143 and 152 to the outside is shown by the reference numeral 130d.

As shown in FIGS. 4 and 6, the gate electrode 143 of the first chip 140 and the gate electrode 152 of the second chip 150 are connected to the outside via the third connector 180 and the second lead 130. Accordingly, the greater part of the current path from the external connection terminal 130d to the gate electrode 143 and the greater part of the current path from the external connection terminal 130d to the gate electrode 152 are a common current path. Therefore, an electrical resistance difference does not easily occur between the current path from the connection terminal 130d to the gate electrode 143 and the current path from the connection terminal 130d to the gate electrode 152.

Similarly, the source electrode 142 of the first chip 140 and the source electrode 151 of the second chip 150 are connected to the outside via the first connector 160 and the first lead 120. Accordingly, the greater part of the current path from the source electrode 142 to the external connection terminal 120d and the greater part of the current path from the source electrode 151 to the external connection terminal 120d are a common current path. Therefore, an electrical resistance difference does not easily occur between the current path from the connection terminal 120d to the source electrode 142 and the current path from the connection terminal 120d to the source electrode 151.

On the other hand, as shown in FIGS. 5 and 6, the drain electrode 141 of the first chip 140 is connected to the outside via the substrate 110; and the drain electrode 153 of the second chip 150 is connected to the outside by the substrate 110 and the second connector 170. Therefore, the greater part of the current path from the external connection terminal 110d to the drain electrode 141 and the greater part of the current path from the external connection terminal 110d to the drain electrode 153 are different. Hereinbelow, the electrical resistance of the common portion of the two current paths in the substrate 110 is taken as an electrical resistance R1; the electrical resistance of only the current path among the two current paths in the substrate 110 that reaches the drain electrode 141 of the first chip 140 is taken as an electrical resistance R2; and the electrical resistance of the second connector 170 is taken as an electrical resistance R3.

The electrical resistance R3 becomes greater than the electrical resistance R2 as the first thickness D1 of the second connector 170 becomes less than the second thickness D2 of the substrate 110. A current flows more easily in the drain electrode 141 of the first chip 140 than in the drain electrode 153 of the second chip 150 as the electrical resistance R3 becomes greater than the electrical resistance R2. In such a case, as the source-drain current of the semiconductor device 100 increases, avalanche breakdown easily occurs in the first chip 140 through which more of the current flows. Conversely, the electrical resistance R2 becomes greater than the electrical resistance R3 as the second thickness D2 of the substrate 110 becomes less than the first thickness D1 of the second connector 170. A current flows more easily in the drain electrode 153 of the second chip 150 than in the drain electrode 141 of the first chip 140 as the electrical resistance R2 becomes greater than the electrical resistance R3. In such a case, as the source-drain current of the semiconductor device 100 increases, avalanche breakdown easily occurs in the second chip 150 through which more of the current flows.

According to the embodiment, the difference between the first thickness D1 and the second thickness D2 is not more than 20% of the thickness of the greater of the first and second thicknesses D1 and D2. Therefore, the difference between the electrical resistance R2 and the electrical resistance R3 can be reduced. As a result, avalanche breakdown due to the flow of an unbalanced current in the first chip 140 or the second chip 150 can be suppressed. Thus, the avalanche resistance of the entire semiconductor device 100 can be improved.

According to the embodiment, the second thickness D2 is less than the first thickness D1. Therefore, the thermal expansion amount of the second connector 170 can be reduced. Thereby, the deformation, damage, etc., of the resin member 190 covering the second connector 170 can be suppressed when the second connector 170 undergoes thermal expansion.

### First Example

A first example of the first embodiment will now be described.

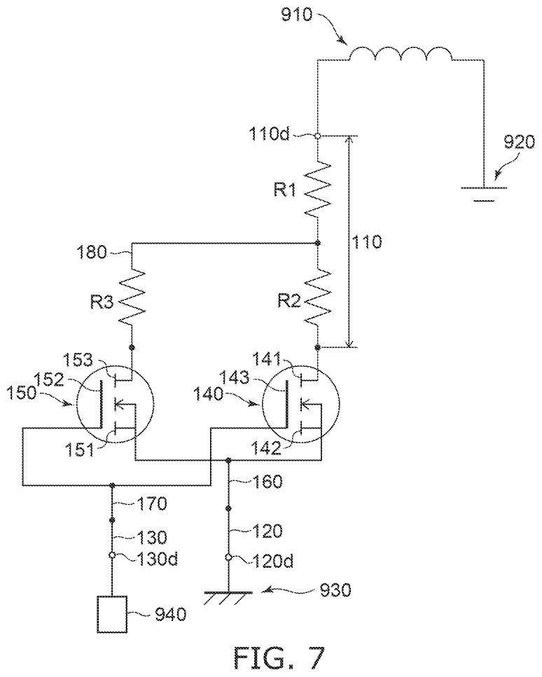

FIG. 7 is an evaluation circuit of semiconductor devices according to reference examples and examples.

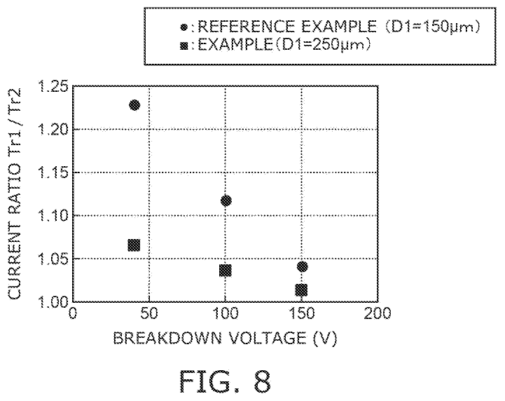

FIG. 8 is a graph showing the relationship between the breakdown voltage and a current ratio Tr1/Tr2.

Semiconductor devices according to reference examples 1 to 3 and semiconductor devices according to examples 1 to 3 were made. Similarly to the first embodiment, the semiconductor devices according to the reference examples 1 to 3 and the semiconductor devices according to the examples 1 to 3 each included the substrate 110, the first lead 120, the second lead 130, the first chip 140, the second chip 150, the first connector 160, the second connector 170, the third connector 180, and the resin member 190, and shared a common configuration other than the first thickness D1 of the second connector 170. In the semiconductor devices according to the reference examples 1 to 3, the first thickness D1 of the second connector 170 was 150 μm; in the semiconductor devices according to the examples 1 to 3, the first thickness D1 of the second connector 170 was 250 μm. The second thickness D2 of the substrate 110 was 300 μm in each of the semiconductor devices according to the reference examples 1 to 3 and the semiconductor devices according to the examples 1 to 3. Accordingly, in the semiconductor devices according to the reference examples 1 to 3, the difference between the first thickness D1 and the second thickness D2 was 150 μm, i.e., 50% of the second thickness D2. In the semiconductor devices according to the examples 1 to 3, the difference between the first thickness D1 and the second thickness D2 was 50 μm, i.e., about 17% of the second thickness D2, i.e., not more than 20% of the second thickness D2.

The breakdown voltage was 40 V for the semiconductor device according to the reference example 1 and the semiconductor device according to the example 1; the breakdown voltage was 100 V for the semiconductor device according to the reference example 2 and the semiconductor device according to the example 2; and the breakdown voltage was 150 V for the semiconductor device according to the reference example 3 and the semiconductor device according to the example 3.

Then, the semiconductor devices according to the reference examples 1 to 3 and the semiconductor devices according to the examples 1 to 3 were embedded in the evaluation circuit shown in FIG. 7; and the current Tr1 flowing in the first chip 140 and a current Tr2 flowing in the second chip 150 were measured. Specifically, the connection terminal 110d was electrically connected to an inductor 910. The inductor 910 was electrically connected to a power supply 920. The connection terminal 120d was electrically connected to earth 930. The connection terminal 130d was electrically connected to a signal source 940.

The ratio Tr1/Tr2 of the currents Tr1 and Tr2 was calculated for each of the semiconductor devices according to the reference examples 1 to 3 and the semiconductor devices according to the examples 1 to 3. The obtained relationships between the breakdown voltage and the current ratio Tr1/Tr2 are shown in FIG. 8. In FIG. 8, the horizontal axis is the breakdown voltage, and the vertical axis is the current ratio Tr1/Tr2. A current ratio Tr1/Tr2 near 1 means that equal currents flowed in the first and second chips 140 and 150.

As shown in FIG. 8, even for the same breakdown voltage, the ratio Tr1/Tr2 was nearer 1 in the semiconductor devices according to the examples 1 to 3 than in the semiconductor devices according to the reference examples 1 to 3. Therefore, the premature breakdown of one of the chips as the source-drain current of the semiconductor device was increased was suppressed, and the avalanche resistance of the entire semiconductor device was improved. Accordingly, it is favorable for the difference between the first thickness D1 and the second thickness D2 to be not more than 20% of the second thickness D2.

The effect of setting the difference between the first thickness D1 and the second thickness D2 to be not more than 20% of the second thickness D2 to cause the ratio Tr1/Tr2 to approach 1 was greater when the breakdown voltage was not more than 100 V than when the breakdown voltage was greater than 100 V. It is considered that this is because the percentage of the total resistance of the semiconductor device due to the electrical resistances R2 and R3 decreases and the percentage due to the internal resistances of the chips 140 and 150 increases as the breakdown voltage increases. Accordingly, it is favorable for the breakdown voltage of the semiconductor device to be not more than 100 V.

### Second Example

A second example of the first embodiment will now be described.

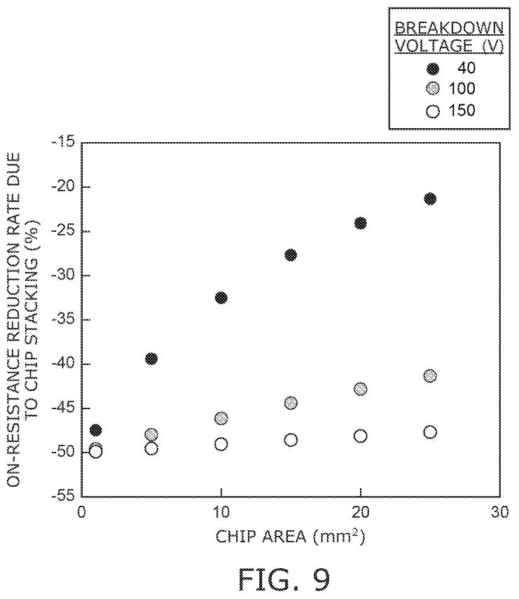

FIG. 9 is a graph showing the effect of stacking the chips, in which the horizontal axis is the chip area of one chip, and the vertical axis is the reduction rate of the on-resistance due to connecting two stacked chips in parallel.

The vertical axis of FIG. 9 is the reduction rate of the on-resistance of the entirety when two of the same chip are stacked and in parallel connected compared to the on-resistance of one chip. The reduction rate of the on-resistance should be −50% when simply calculating based on only the internal resistance of the chip.

As shown in FIG. 9, the reduction rate of the on-resistance becomes pronounced as the chip area decreases. It is considered that this is because reducing the chip area increases the resistance of the transistor part, which increases the percentage of the total resistance due to the resistance of the transistor part; therefore, the resistance reduction of the transistor part by stacking increases the total resistance reduction ratio. Accordingly, it is favorable for the chip area of the first chip 140 and the chip area of the second chip 150 when viewed from above each to be not less than 10 mm² and not more than 25 mm².

### Second Embodiment

A second embodiment will now be described.

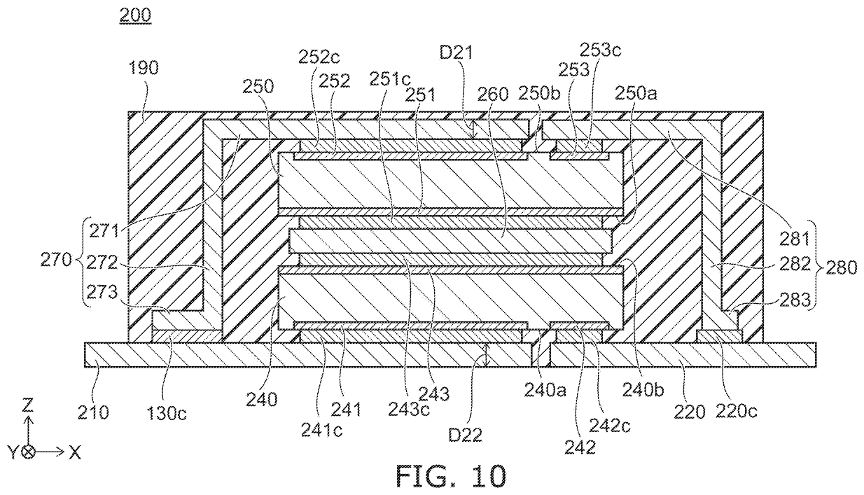

FIG. 10 is a cross-sectional view showing a semiconductor device according to the embodiment.

The orientation of a first chip 240 and the orientation of a second chip 250 in the semiconductor device 200 according to the embodiment are different from those of the semiconductor device 100 according to the first embodiment.

The differences with the first embodiment are mainly described in the following description. Other than the items described below, the configuration can be similar to the first embodiment. This is similar for other embodiments described below as well.

A source electrode 241 and a gate electrode 242 are located at a lower surface 240a of the first chip 240. The source electrode 241 faces an electrically-conductive first substrate 210 and is electrically connected to the first substrate 210 via a bonding layer 241c. The gate electrode 242 faces an electrically-conductive second substrate 220 and is electrically connected to the second substrate 220 via a bonding layer 242c.

A drain electrode 243 is located at an upper surface 240b of the first chip 240. The drain electrode 243 faces a first connector 260. The drain electrode 243 is electrically connected to the first connector 260 via a bonding layer 243c. Similarly to the first connector 160 according to the first embodiment, the first connector 260 is connected to a drain lead (not illustrated).

A drain electrode 251 is located at a lower surface 250a of the second chip 250. The drain electrode 251 faces the first connector 260. The drain electrode 251 is electrically connected to the first connector 260 via a bonding layer 251c.

A source electrode 252 and a gate electrode 253 are located at an upper surface 250b of the second chip 250. The source electrode 252 faces a second connector 270. The source electrode 252 is electrically connected to the second connector 270 via a bonding layer 252c. The gate electrode 253 faces a third connector 280. The gate electrode 253 is electrically connected to the third connector 280 via a bonding layer 253c.

The second connector 270 includes a first part 271 positioned above the second chip 250, a second part 272 extending from the first part 271 toward the first substrate 210, and a third part 273 that is linked to the lower end of the second part 272 and extends in a direction along the front surface of the first substrate 210. The difference between a first thickness D21 of the first part 271 and a second thickness D22 of the portion of the first substrate 210 overlapping the source electrode 241 when viewed from above is not more than 20% of the greater of the first and second thicknesses D21 and D22 (in FIG. 10, the second thickness D22).

Similarly, the third connector 280 includes a first part 281 positioned above the second chip 250, a second part 282 extending from the first part 281 toward the second substrate 220, and a third part 283 that is linked to the lower end of the second part 282 and extends in a direction along the front surface of the second substrate 220.

In such a semiconductor device 200 as well, by setting the difference between the first thickness D21 and the second thickness D22 to be not more than 20% of the greater of the first and second thicknesses D21 and D22, the difference between the electrical resistance of the current path from the first substrate 210 to the source electrode 241 of the first chip 240 and the electrical resistance of the current path from the first substrate 210 to the source electrode 252 of the second chip 250 via the second connector 270 can be reduced, and the concentration of the current in one chip can be suppressed. As a result, the avalanche resistance of the semiconductor device 200 can be improved.

### Third Embodiment

A third embodiment will now be described.

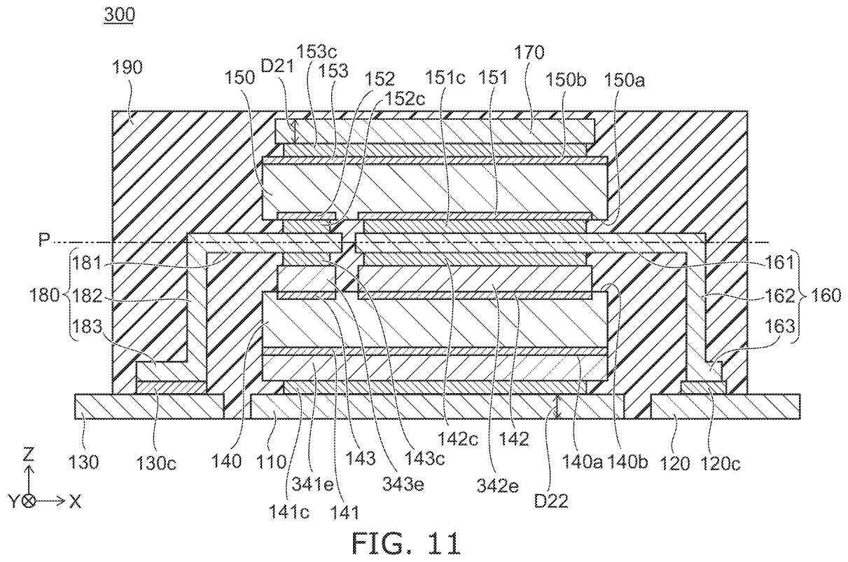

FIG. 11 is a cross-sectional view showing a semiconductor device according to the embodiment.

As shown in FIG. 11, the semiconductor device 300 according to the embodiment differs from the semiconductor device 100 according to the first embodiment in that the semiconductor device 300 further includes multiple metal layers 341e, 342e, and 343e.

According to the embodiment, the second thickness D2 is greater than the first thickness D1. The difference between the first thickness D1 and the second thickness D2 is not more than 20% of the second thickness D2. Therefore, a current flows more easily in the first chip 140 than in the second chip 150. However, the difference between the first thickness D1 and the second thickness D2 may be greater than 20% of the second thickness D2. In other words, the difference between the first thickness D1 and the second thickness D2 may be greater than 20% of the greater of the first and second thicknesses D1 and D2.

The metal layer 341e is positioned between the drain electrode 141 and the bonding layer 141c. The metal layer 341e is electrically connected with the bonding layer 141c and the drain electrode 141 by contacting the upper surface of the bonding layer 141c and the lower surface of the drain electrode 141. The metal layer 342e is positioned between the source electrode 142 and the bonding layer 142c. The metal layer 342e is electrically connected with the source electrode 142 and the bonding layer 142c by contacting the upper surface of the source electrode 142 and the lower surface of the bonding layer 142c. The metal layer 343e is positioned between the gate electrode 143 and the bonding layer 143c. The metal layer 343e is electrically connected with the gate electrode 143 and the bonding layer 143c by contacting the upper surface of the gate electrode 143 and the lower surface of the bonding layer 143c. The metal layers 341e, 342e, and 343e each spread along the X-Y plane.

The thermal conductivities of the metal layers 341e, 342e, and 343e are greater than the thermal conductivities of the bonding layers 141c, 142c, and 143c. The metal layers 341e each include, for example, at least one of gold, silver, or copper. Although not particularly limited, the thicknesses of the metal layers 341e, 342e, and 343e are, for example, not less than 10 μm and not more than 20 μm. On the other hand, for example, the bonding layers 141c, 142c, and 143c are made of solder. Generally, the thermal conductivity of solder is low.

In the semiconductor device 300 according to the embodiment, the current flows more easily in the first chip 140 than in the second chip 150 because the second thickness D2 is greater than the first thickness D1. Therefore, the metal layers 341e, 342e, and 343e are located respectively on the electrodes 141, 142, and 143 of the first chip 140. Thereby, the heat that is generated at portions in the first chip 140 at which the current is particularly concentrated can be diffused along the X-Y plane, and the temperature in the first chip 140 can be made uniform. Thermal breakdown at portions in the first chip 140 at which the current is concentrated can be suppressed thereby, and the avalanche breakdown of the first chip 140 can be suppressed. As a result, the avalanche resistance of the semiconductor device 300 can be improved.

According to the embodiment, the metal layers are located at the first chip 140 side of the bonding layers. Thereby, the heat from the first chip 140 is directly conducted to the metal layers without going through the bonding layers that have low thermal conductivities. As a result, the heat can be effectively diffused by the metal layers, and the avalanche resistance of the semiconductor device 300 is reliably improved.

### Test Example

A test example of the third embodiment will now be described.

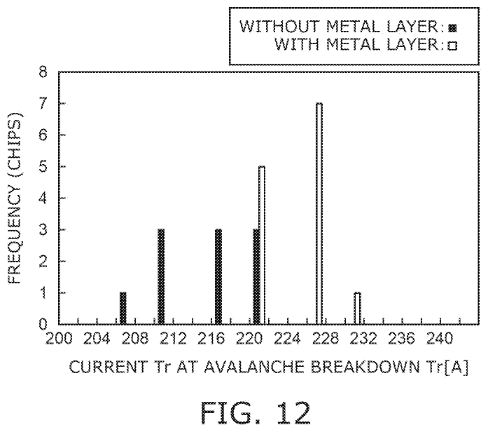

FIG. 12 is a histogram in which the horizontal axis is the current flowing in the chip when avalanche breakdown occurred, and the vertical axis is the occurrence frequency of chips measured at each current.

Ten chips that had configurations similar to the first and second chips 140 and 150 and included metal layers made of copper having a thickness of 10 μm respectively on the drain electrode, the source electrode, and the gate electrode were prepared. Also, ten chips that had configurations similar to the first and second chips 140 and 150 and did not include metal layers on the drain electrode, the source electrode, and the gate electrode were prepared. Then, a current Tr at which avalanche breakdown of the chip occurred was measured. The results are shown in FIG. 12.

As shown in FIG. 12, it was found that breakdown of the chips that included the metal layers on the electrodes tended to occur at higher currents Tr. In other words, it was found that the avalanche resistance of the chips can be improved by including metal layers on the chip electrodes. For the average value of the currents Tr of the chips, the avalanche resistance was about 10% better when the metal layers were included than when the metal layers were not included.

However, the metal layer may not be provided on all of the electrodes of the first chip. Also, the second thickness may be greater than the first thickness. In such a case, the current flows more easily in the second chip than in the first chip. Therefore, in such a case, the heat that is generated in the second chip can be efficiently made uniform by providing the metal layer on the electrode of the second chip. In other words, when the first thickness is less than the second thickness, the metal layer may be provided on any of the electrodes of the first chip; and when the first thickness is greater than the second thickness, the metal layer may be provided on any of the electrodes of the second chip. Also, such a metal layer may be included in the semiconductor device according to the second embodiment.

### Fourth Embodiment

A fourth embodiment will now be described.

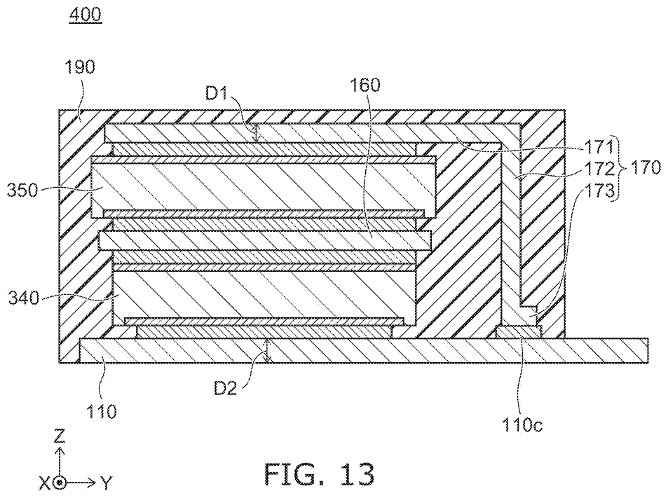

FIG. 13 is a cross-sectional view showing a semiconductor device according to the embodiment.

FIG. 13 corresponds to FIG. 5 of the first embodiment.

The semiconductor device 400 according to the embodiment differs from the semiconductor device 100 according to the first embodiment in that the chip through which the current more easily flows has a smaller chip area than the chip through which the current less easily flows.

In the semiconductor device 400 as shown in FIG. 13, the second thickness D2 of the substrate 110 is greater than the first thickness D1 of the first part 171 of the second connector 170. Therefore, the current would easily concentrate in a first chip 340 if the first chip 340 and a second chip 350 were chips of the same specification. Therefore, according to the embodiment, the chip area of the first chip 340 is set to be less than the chip area of the second chip 350. Thereby, the internal resistance of the first chip 340 can be greater than the internal resistance of the second chip 350, and the concentration of the current in the first chip 340 can be suppressed. The avalanche resistance of the entire semiconductor device 400 is improved thereby.

Although examples are shown in the embodiments described above in which the substrate and the second connector are formed of the same material, the substrate and the second connector are not limited thereto. For example, when the substrate is thicker than the second connector, the material included in the substrate may have a higher electrical resistivity than the material included in the second connector. For example, the substrate may be formed of aluminum (having an electrical resistivity of 28.2 nΩ·m at 20° C.); and the second connector may be formed of copper (having an electrical resistivity of 16.8 nΩ·m at 20° C.).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

What is claimed is:

1. A semiconductor device, comprising:
a substrate having a second thickness and being electrically-conductive;
a first chip including
a first surface facing the substrate,
a second surface positioned at a side opposite to the first surface,
a first electrode located at the first surface and electrically connected to the substrate, and
a second electrode located at the second surface;
a second chip including
a third surface facing the second surface,
a fourth surface positioned at a side opposite to the third surface,
a third electrode located at the third surface, and
a fourth electrode located at the fourth surface;
a first connector located between the second electrode and the third electrode and electrically connected to the second and third electrodes; and
a second connector electrically connected to the substrate and the fourth electrode,
the second connector including a first part positioned above the second chip,
a difference between the second thickness and a first thickness of the first part being not more than 20% of the greater of the first thickness or the second thickness.

2. The device according to claim 1, wherein
the first thickness is less than the second thickness.

3. The device according to claim 1, further comprising:
a first bonding layer positioned between the first electrode and the substrate, the first bonding layer being electrically-conductive;
a second bonding layer positioned between the second electrode and the first connector, the second bonding layer being electrically-conductive;
a third bonding layer positioned between the third electrode and the first connector, the third bonding layer being electrically-conductive;
a fourth bonding layer positioned between the fourth electrode and the second connector, the fourth bonding layer being electrically-conductive; and
a metal layer having a higher thermal conductivity than the first to fourth bonding layers,
when the first thickness is less than the second thickness, the metal layer is located between the first bonding layer and the first electrode or between the second bonding layer and the second electrode,
when the first thickness is greater than the second thickness, the metal layer is located between the third bonding layer and the third electrode or between the fourth bonding layer and the fourth electrode.

4. The device according to claim 1, wherein
the second connector further includes a second part extending from the substrate toward the first part, and
a thickness of the second part is less than a thickness of the first part.

5. The device according to claim 1, wherein
a surface area of the first chip and a surface area of the second chip when viewed from above each are not less than 10 mm² and not more than 25 mm².

6. A semiconductor device, comprising:
a substrate that is electrically-conductive;
a first chip including
a first surface facing the substrate,
a second surface positioned at a side opposite to the first surface,
a first electrode located at the first surface and electrically connected to the substrate, and
a second electrode located at the second surface;
a second chip including
a third surface facing the second surface,
a fourth surface positioned at a side opposite to the third surface,
a third electrode located at the third surface, and
a fourth electrode located at the fourth surface;
a first connector located between the second electrode and the third electrode and electrically connected to the second and third electrodes;
a second connector electrically connected to the substrate and the fourth electrode, the second connector including a first part positioned above the second chip;
a first bonding layer positioned between the first electrode and the substrate, the first bonding layer being electrically-conductive;
a second bonding layer positioned between the second electrode and the first connector, the second bonding layer being electrically-conductive;
a third bonding layer positioned between the third electrode and the first connector, the third bonding layer being electrically-conductive;
a fourth bonding layer positioned between the fourth electrode and the second connector, the fourth bonding layer being electrically-conductive; and
a metal layer having a higher thermal conductivity than the first to fourth bonding layers,
the metal layer being located in at least one of between the first bonding layer and the first electrode, between the second bonding layer and the second electrode, between the third bonding layer and the third electrode, or between the fourth bonding layer and the fourth electrode.

7. The device according to claim 6, wherein
when a first thickness of the first part is less than a second thickness of a portion of the substrate overlapping the first electrode when viewed from above, the metal layer is located between the first bonding layer and the first electrode or between the second bonding layer and the second electrode, and
when the first thickness is greater than the second thickness, the metal layer is located between the third bonding layer and the third electrode or between the fourth bonding layer and the fourth electrode.

8. The device according to claim 7, wherein
the first thickness is less than the second thickness, and
the metal layer is located both between the first bonding layer and the first electrode and between the second bonding layer and the second electrode.

9. The device according to claim 6, wherein
the second connector further includes a second part extending from the substrate toward the first part, and
a thickness of the second part is less than a thickness of the first part.

10. The device according to claim 6, wherein
a surface area of the first chip and a surface area of the second chip when viewed from above each are not less than 10 mm² and not more than 25 mm².

11. A semiconductor device, comprising:
a substrate that is electrically-conductive;
a first chip including
a first surface facing the substrate,
a second surface positioned at a side opposite to the first surface,
a first electrode located at the first surface and electrically connected to the substrate, and
a second electrode located at the second surface,
a second chip including
a third surface facing the second surface,
a fourth surface positioned at a side opposite to the third surface,
a third electrode located at the third surface, and
a fourth electrode located at the fourth surface, a surface area of the second chip being greater than a surface area of the first chip when viewed from above;
a first connector located between the second electrode and the third electrode and electrically connected to the second and third electrodes; and
a second connector electrically connected to the substrate and the fourth electrode,
the second connector including a first part positioned above the second chip,
a first thickness of the first part being less than a second thickness of a portion of the substrate overlapping the first electrode when viewed from above.

12. The device according to claim 11, wherein
the second connector further includes a second part extending from the substrate toward the first part, and
a thickness of the second part is less than a thickness of the first part.

13. The device according to claim 11, wherein
a surface area of the first chip and a surface area of the second chip when viewed from above each are not less than 10 mm² and not more than 25 mm².
